(19) United States
(12) Patent Application Publication
(10) Pub. No.: US 2012/0152730 A1
(43) Pub. Date: Jun. 21, 2012

(54) GLASS COMPOSITION FOR ULTRAVIOLET LIGHT AND OPTICAL DEVICE USING THE SAME

(75) Inventors: Taihei Mukaide, Atsugi-shi (JP); Tomohiro Watanabe, Yokohama-shi (JP); Hidenosuke Itoh, Tokyo (JP)

(73) Assignee: CANON KABUSHIKI KAISHA, Tokyo (JP)

(21) Appl. No.: 13/402,909

(22) Filed: Feb. 23, 2012

Related U.S. Application Data
(62) Division of application No. 12/443,557, filed on Mar. 30, 2009.

(30) Foreign Application Priority Data
Nov. 21, 2006 (JP) 2006-314753

(51) Int. Cl. C23C 14/34

(52) U.S. Cl. 204/192.26; 204/298.13

(57) ABSTRACT

A glass composition for ultraviolet light is provided. The glass composition for ultraviolet light contains Lu, Al, and O in an amount of 99.99 weight % or more in total. The glass composition contains Lu in an amount of 24% or more and 33% or less in cation percent and Al in an amount of 67% or more and 76% or less in cation percent.

### TECHNICAL FIELD

The present invention relates to a glass composition for ultraviolet light, particularly an oxide glass composition suitable for an optical member used in an optical device.

### BACKGROUND ART

An optical member is utilized in a wide range of fields such as a camera and a telescope. The optical member can be roughly classified into two types using a crystal as a raw material and glass as the raw material. A crystalline optical member of these optical members is divided in use depending on a crystal system. An optical member used as a lens in an imaging optical system is formed of a cubic crystal. By using an optically isotropic cubic crystal, it is possible to reduce birefringence or the like due to optical anisotropy.

As a glass composition, International Publication No. WO 01/27046 describes glass containing aluminum oxide in an amount of 50 molar % or more and 77 molar % and rare earth oxides in an amount of 25 molar % or more and 50 molar % or less. This publication also discloses lutetium (Lu) as a rare earth element.

With high integration of a semiconductor integrated circuit, demands on ultrafine pattern formation have increasingly grown. A reduced projection exposure device (stepper) of a step-and-repeat type for transferring a minute pattern onto a wafer grows more sophisticated, so that a wavelength of a light source for exposure is shifted to a short wavelength. An optical member which receives attention in optical members for that purpose is a cubic calcium fluoride single crystal having a high transmittance in an ultraviolet region. Further, in recent years, development of optical members using Lu, AL, Mg, and the like higher in refractivity than Si has been tried in order to realize a high refractive index of an optical member for the purpose of providing a higher resolution. For example, development of cubic crystals such as lutetium aluminum garnet single crystal (Lu₃Al₅O₁₂), magnesium oxide single crystal (MgO), and magnesium spinel single crystal (MgAl₂O₄) have been actively carried out. Particularly, the lutetium aluminum garnet single crystal has a high refractive index, thus being expected for future development. For example, the lutetium aluminum garnet single crystal has a refractive index of 2.1 at a wavelength of 193 nm. Quartz glass has a refractive index of 1.56 at the wavelength of 193 nm and the calcium fluoride single crystal has a refractive index of 1.50 at the wavelength of 193 nm.

In the single crystal materials, there arises a problem of an occurrence of intrinsic birefringence (IBR). MgO and Al₂O₄ have IBR values of 70 nm/cm (extrapolated value) and 52 nm/cm (extrapolated value), which are considerably larger than that (3.4 nm/cm) of CaF₂ (John H. Burnett, Simon G, Kaplan, Eric L. Shirley, Paul J. Tompkins, and James E. Webb, “High-Index Materials for 193 nm Immersion Lithography, Proceedings of the SPIE, Volume 5754, pp. 611-621 (2005)).

For this reason, development of a material causing no IBR is required. As an example of development of a high-refractive index optical member having a high transmittance in the ultraviolet region, an attempt is made to increase the refractive index by realizing permanent high density of quartz glass under application of a pressure (Phys. Chem. Glasses 10, 117 (1969)). However, a change in refractive index by the pressure application is small, so that the above described high-refractive index optical member has not been put into practical use.

In summary, it is difficult to increase the refractive index of the quartz glass, and the crystalline optical member such as the lutetium aluminum garnet single crystal causes the IBR. Further, when the above described optical members are used in an immersion exposure device as an optical device, the optical members have not been sufficient in terms of various characteristics.

### DISCLOSURE OF THE INVENTION

The present invention has been accomplished in view of the above-described circumstances. A principal object of the present invention is to provide a glass composition for ultraviolet light causing no problem of an occurrence of intrinsic birefringence (IBR).

Another object of the present invention is to provide a glass composition for ultraviolet light having a high refractive index and a high transmittance and causing less or no IBR and less or no stress birefringence (SBR).

A further object of the present invention is to provide a glass composition for ultraviolet light having a resistance to light of a light source and a resistance to a liquid used.

A still further object of the present invention is to provide optical devices using the above-described glass composition for ultraviolet lights.

According to an aspect of the present invention, there is provided a glass composition for ultraviolet light, comprising:

Lu, Al, and O in an amount of 99.99 weight % or more in total,

wherein the glass composition contains Lu in an amount of 24% or more and 33% or less in cation percent and Al in an amount of 67% or more and 76% or less in cation percent.

According to another aspect of the present invention, there is provided an optical device comprising:

a light source for generating ultraviolet light; and

an optical system for irradiating an object with the ultraviolet light from the light source,

wherein the optical system includes an optical member comprising a base material and/or an optical thin film, and

wherein the base material and/or the optical thin film comprises a glass composition for ultraviolet light, comprising:

Lu, Al, and O in an amount of 99.99 weight % or more in total,

wherein the glass composition contains Lu in an amount of 24% or more and 33% or less in cation percent and Al in an amount of 67% or more and 76% or less in cation percent.

According to a further aspect of the present invention, there is provided an optical device comprising:

a light source for generating ultraviolet light; and

an optical system for irradiating an object with the ultraviolet light from the light source,

wherein the optical system includes a first optical member and a second optical member having a refractive index larger than that of the first optical member, and

wherein the second optical member comprises a base material comprising a glass composition for ultraviolet light, comprising:

Lu, Al, and O in an amount of 99.99 weight % or more in total,

wherein the glass composition contains Lu in an amount of 24% or more and 33% or less in cation percent and Al in an amount of 67% or more and 76% or less in cation percent.

As a result of study on glass materials free from IBR, the present inventors have found that a composition of Lu, Al, and O is not crystallized but is vitrified (changed into an amorphous substance) when the composition of Lu, Au, and O is in a particular range as described above. An oxide of Lu itself is little vitrified but has a higher refractive index (1.933 at a wavelength of 587.6 nm) compared with a refractive index (1.458 at a wavelength of 587.6 nm) of an oxide of Si. The composition of an Lu oxide and an Al oxide in the particular range is vitrified to constitute a glass composition having a high refractive index.

According to the present invention, with respect to ultraviolet lights having wavelengths of 365 nm, 248 nm, 193 nm, and the like, it is possible to provide a glass composition having solved the above described problem of the occurrence of the IBR (intrinsic birefringence).

Further, according to the present invention, it is possible to provide a glass composition for ultraviolet light having a low SBR (stress birefringence) and resistances to ultraviolet light and a liquid used and provide an optical device using the glass composition for ultraviolet light.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic view showing an optical device according to an embodiment of the present invention.

FIG. 2 is a schematic view showing a gas jet levitation device.

FIG. 3 is a graph showing an X-ray scattering pattern of glass obtained in Example 1 of the present invention.

FIG. 4 is a schematic view showing an X-ray diffracting device.

FIG. 5 is an X-ray photograph showing an X-ray scattering pattern of glass obtained in Example 4 of the present invention.

### BEST MODE FOR CARRYING OUT THE INVENTION

Embodiments for carrying out the present invention are shown below. However, it should be understood that the following description does not limit the scope of the present invention unless otherwise specified.

### Embodiment 1

A glass composition according to Embodiment 1 of the present invention contains Lu, Al, and O in an amount of 99.99 weight (wt.) % in total and contains Lu in an amount of 24% or more and 33% or less in cation percent and Al in an amount of 67% or more and 76% or less in cation percent.

In an oxide glass composition, when a main component of the glass is consisting of Lu, AL, and O, a vitrifiable range is determined by contents thereof. Vitrification is performed by a method in which melt of a target composition is prepared and abruptly cooled or by a vapor phase synthesizing method such as chemical vapor deposition (CVD) or the like.

The glass composition of this embodiment contains Lu, Al, and O in the total amount of 99.99 wt. %, preferably in a total amount unlimitedly closer to 100 wt. %. As described above, this glass composition contains Lu in the amount of 28% or more and 32% or less in cation percent and Al in the amount of 68% or more and 72% or less in cation percent. When the contents of Lu and Al are within these ranges, the composition is changed into an amorphous substance, thus being preferable since the problem of the intrinsic birefringence (IBR) does not arise.

Herein, the cation percent of Lu means a ratio of the ion number of a cation of Lu to the sum of the ion number of cations of Lu and Al. The cation percent of Al means a ratio of the ion number of the cation of Lu to the sum of the ion number of the cations of Lu and Al.

The glass composition of Lu, Al, and O described above may preferably be consisting of Lu₂O₃ and Al₂O₃. In this case, the contents of Lu₂O₃ and Al₂O₃ may preferably be represented by Lu in the amount of 24% or more and 33% or less in cation percent and Al in the amount of 67% or more and 76% or less in cation percent.

In the glass composition, an impurity impairs vitrification and generates a defective portion in many cases, so that the content thereof may appropriately be controlled in an amount of 100 ppm or less. On the other hand, boron (B) may be added to the glass composition as desired.

The above-described glass composition itself can be utilized as not only a base material (glass material) of a lens but also a sputtering target to be used for forming an optical thin film.

These lens and optical thin film may suitably be used as an optical member through which ultraviolet light with a wavelength of 365 nm or less, preferably 248 nm or less, further preferably 193 nm or less, passes.

### Embodiment 2

In an exposure device as an optical device according to Embodiment 2 of the present invention, a light source for generating light in a vacuum ultraviolet region with a wavelength of 200 nm or less (e.g., ArF excimer laser; oscillation wavelength=193 nm) is used. This is because a resolution line width is smaller with a smaller exposure wavelength and a larger numerical aperture, thus improving a resolution.

In this embodiment, a liquid is filled between an exposure substrate and a final lens of the exposure device to substantially decrease a wavelength of light at the surface of the exposure substrate, thus constituting an immersion exposure device for improving a resolution.

The immersion exposure device at least includes the light source, an illumination optical system, an optical mask (reticle), a projection optical system, and a supply/recovery device for the liquid. Exposure to light is performed in a state in which the liquid is filled between a lens (final lens) provided at an end of the projection optical system close to the exposure substrate and the exposure substrate provided with a photosensitive film.

The final lens of such an immersion exposure device is required to have a high refractive index and a high transmittance at a wavelength of light from the light source. Further, the final lens is also required to cause less or no birefringence (IBR and SBR). In addition, the final lens is required to have resistances to the light from the light source and the liquid used. For these increases, in Embodiment 2, the lens comprising the glass composition described in Embodiment 1 is used as the final lens. As lenses other than the final lens, lenses of quartz glass are used.

On these lenses, an optical thin film for preventing reflection is formed as desired.

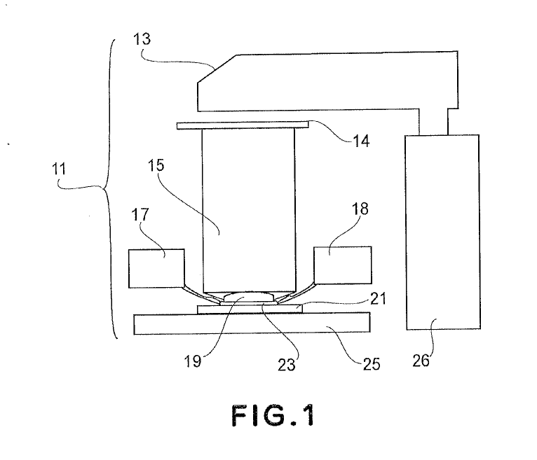

FIG. 1 is a schematic view of the immersion exposure device.

Referring to FIG. 1, an immersion exposure device 11 includes an illumination optical system 13, an optical mask (reticle) 14, a projection optical system 15 separated from the illumination optical system 13 by the mask 14, liquid supply/recovery devices 17 and 18, a stage 25 capable of moving an exposure substrate, and a laser light source 26.

The projection optical system 15 includes lenses formed of quartz glass as a first optical member having a relatively low refractive index and a final lens 19 as a second optical member having a relatively high refractive index. The projection optical system 15 effects exposure by irradiating an exposure substrate 21 provided with a photosensitive film as an objected (to be exposed) with ultraviolet light in a state in which a liquid 23 is filled between the final lens 19 and the exposure substrate 21 provided with the photosensitive film.

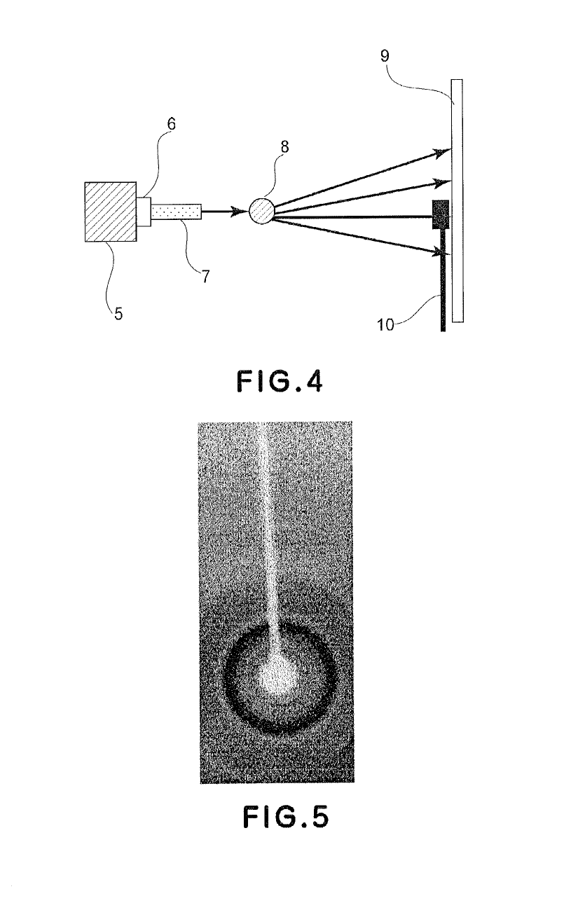

By this exposure, a pattern of the optical mask (reticle) 14 is reduced in size and can be transferred onto the exposure substrate 21. In FIG. 4, the liquid 23 is held only between the final lens 19 and the exposure substrate 21 but is not limited thereto. For example, the entire substrate 21 may also be immersed in the liquid 23. As the liquid 23, it is possible to use pure water having a refractive index (at 20° C.) of 1.44 with respect to a wavelength of 193 nm and a fluorine-containing organic solvent.

The immersion exposure device of Embodiment 2 may preferably include a laser light source with a wavelength of 200 nm as the light source. More specifically, the immersion exposure device includes an ArF excimer laser oscillator or an F2 excimer laser oscillator. By using such a laser light source with a short wavelength as the light source, a resolution of the resultant exposure device can be improved.

The optical member according to this embodiment is suitably used as an optical member for an exposure device transparent to vacuum ultraviolet light with a wavelength of 193 nm.

### Embodiment 3

An optical device according to Embodiment 3 of the present invention includes a light source for generating ultraviolet light and an optical system for irradiating an object with the ultraviolet light from the light source. The optical system includes an optical member comprising a base material and/or an optical thin film. The base material and/or the optical thin film comprises a glass composition for ultraviolet light, comprising: Lu, Al, and O in an amount of 99.99 weight % or more in total, wherein the glass composition contains Lu in an amount of 24% or more and 33% or less in cation percent and Al in an amount of 67% or more and 76% or less in cation percent.

In other words, a lens is prepared by using the above-described glass composition for ultraviolet light itself as the base material.

Alternatively, an optical member lens such as a lens or a mirror is prepared by forming an optical thin film with a high refractive index on a surface of the base material such as a silicon wafer or quartz glass through sputtering using the above-described glass composition for ultraviolet light as a target. The optical thin film is characterized by containing Lu, Al, and O in an amount of 99.99 weight % or more in total and containing Lu in an amount of 24% or more and 33% or less in cation percent and Al in an amount of 67% or more and 76% or less in cation percent.

The optical member according to this embodiment is suitably used as an optical member for an optical device transparent to ultraviolet light with a wavelength of 365 nm or less, preferably 248 nm or less, further preferably 193 nm or less.

The present invention is described more specifically based on Examples below.

### Example 1

As starting materials for synthesizing glass, Lu₂O₃ (purity: 99.99 wt. %) and Al₂O₃ (purity: 99.998 wt. %) were used. These starting materials were weighed and sufficiently mixed in a mortar in a weight ratio (Lu₂O₃:Al₂O₃) of 1.92:1 so that Lu₂O₃ and Al₂O₃ contain Lu in an amount of 33% in cation percent and Al in an amount of 67% in cation percent, respectively. Thereafter, about 100 mg of the mixture was partly melted by irradiation with a carbon dioxide gas laser and an output of the laser was lowered, so that a spherical polycrystalline aggregate was prepared.

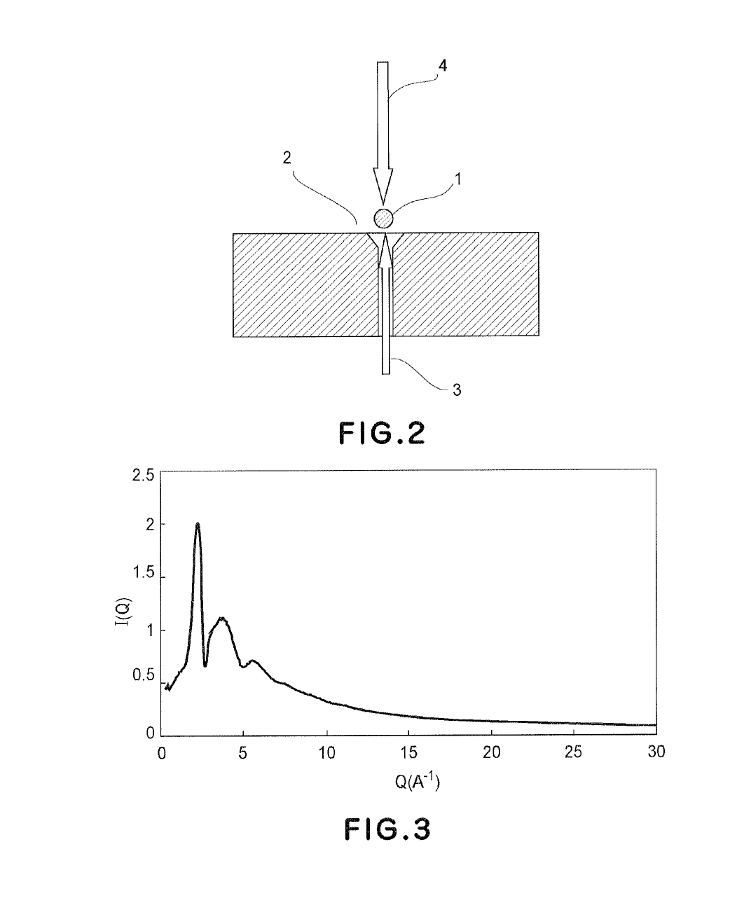

This polycrystalline aggregate as a sample 1 was set on a copper nozzle 2 of the gas jet levitation device shown in FIG. 2 and was then heated again by the carbon dioxide gas laser 4 in a floating state created by using Ar gas 3, thus being completely melted. In that state, the output of the laser was cut off to abruptly cool the sample 1, so that a transparent spherical material was obtained. This process was monitored by a radiation pyrometer with respect to a temperature but an exothermic reaction due to crystallization was not observed.

This transparent spherical material was examined with respect to the presence or absence of a crystal by an X-ray diffraction method, FIG. 3 shows an X-ray scattering intensity curve of the transparent spherical material. In FIG. 3, an abscissa represents Q (=4 π sin θ/λ) and an ordinate represents a scattering intensity I(Q). As a light source, an X-ray monochromatized to 113.4 KeV was used. Three or four spherical samples (diameter: 2-3 mm) were placed in a capillary of SiO₂ glass or interposed between kapton films and scattering X-ray from the samples was measured by a Ge solid detector. From the scattering pattern shown in FIG. 3, a diffraction pattern showing crystallinity was not found and the scattering pattern was a halo pattern characterizing glass, so that it was confirmed that the transparent spherical material in this example was a glass (amorphous material).

### Example 2

As starting materials for synthesizing glass, Lu₂O₃ (purity: 99.99 wt. %) and Al₂O₃ (purity: 99.998 wt. %) were used. These starting materials were weighed and sufficiently mixed in a mortar in a weight ratio (Lu₂O₃:Al₂O₃) of 1.67:1 so that Lu₂O₃ and Al₂O₃ contain Lu in an amount of 30% in cation percent and Al in an amount of 70% in cation percent, respectively. Thereafter, about 100 mg of the mixture was partly melted by irradiation with a carbon dioxide gas laser and an output of the laser was lowered, so that a spherical polycrystalline aggregate was prepared.

This polycrystalline aggregate as a sample 1 was set on a copper nozzle 2 of the gas jet levitation device shown in FIG. 2 and was then heated again by the carbon dioxide gas laser 4 in a floating state created by using Ar gas 3, thus being completely melted. In that state, the output of the laser was cut off to abruptly cool the sample, so that it was possible to obtain a transparent spherical glass.

### Example 3

As starting materials for synthesizing glass, Lu₂O₃ (purity: 99.99 wt. %) and Al₂O₃ (purity: 99.998 wt. %) were used. These starting materials were weighed and sufficiently mixed in a mortar in a weight ratio (Lu₂O₃:Al₂O₃) of 1.23:1 so that Lu₂O₃ and Al₂O₃ contain Lu in an amount of 24% in cation percent and Al in an amount of 76% in cation percent, respectively. Thereafter, about 100 mg of the mixture was partly melted by irradiation with a carbon dioxide gas laser and an output of the laser was lowered, so that a spherical polycrystalline aggregate was prepared.

This polycrystalline aggregate as a sample 1 was set on a copper nozzle 2 of the gas jet levitation device shown in FIG. 2 and was then heated again by the carbon dioxide gas laser 4 in a floating state created by using Ar gas 3, thus being completely melted. In that state, the output of the laser was cut off to abruptly cool the sample, so that it was possible to obtain a transparent spherical glass.

### Example 4

As starting materials for synthesizing glass, Lu₂O₃ (purity: 99.99 wt. %) and Al₂O₃ (purity: 99.998 wt. %) were used. These starting materials were weighed and sufficiently mixed in a mortar in a weight ratio (Lu₂O₃:Al₂O₃) of 1.44:1 so that Lu₂O₃ and Al₂O₃ contain Lu in an amount of 27% in cation percent and Al in an amount of 73% in cation percent, respectively. Thereafter, about 100 mg of the mixture was partly melted by irradiation with a carbon dioxide gas laser and an output of the laser was lowered, so that a spherical polycrystalline aggregate was prepared.

This polycrystalline aggregate as a sample 1 was set on a copper nozzle 2 of the gas jet levitation device shown in FIG. 2 and was then heated again by the carbon dioxide gas laser 4 in a floating state created by using Ar gas 3, thus being completely melted. In that state, the output of the laser was cut off to abruptly cool the sample, so that it was possible to obtain a transparent spherical material.

This transparent spherical material was examined with respect to the presence or absence of a crystal by an X-ray diffraction method. FIG. 4 shows a layout diagram of an X-ray diffracting device. In FIG. 4, as a radiation source of an X-ray generating device 5, MO was used and X-ray was monochromatized by a graphite monochromator 6. Thereafter, the X-ray was changed to a beam of 0.8 mm in diameter by a collimator 7 and entered a sample 8. Scattering X-ray from the samples was recorded by an imaging plate 9. In front of the imaging plate 9, a beam stopper 10 is disposed. The resultant scattering pattern is shown in FIG. 5. As understood from the scattering pattern shown in FIG. 5, a diffraction pattern showing crystallinity was not found and scattering from glass was confirmed, so that it was confirmed that the transparent spherical material in this example was a glass (amorphous material).

### Comparative Example 1

As starting materials for synthesizing glass, Lu₂O₃ (purity: 99.99 wt. %) and Al₂O₃ (purity: 99.998 wt. %) were used. These starting materials were weighed and sufficiently mixed in a mortar in a weight ratio (Lu₂O₃:Al₂O₃) of 1.10:1 so that Lu₂O₃ and Al₂O₃ contain Lu in an amount of 22% in cation percent and Al in an amount of 78% in cation percent, respectively. Thereafter, about 100 mg of the mixture was partly melted by irradiation with a carbon dioxide gas laser and an output of the laser was lowered, so that a spherical polycrystalline aggregate was prepared.

This polycrystalline aggregate as a sample 1 was set on a copper nozzle 2 of the gas jet levitation device shown in FIG. 2 and was then heated again by the carbon dioxide gas laser 4 in a floating state created by using Ar gas 3, thus being completely melted. In that state, the output of the laser was cut off to abruptly cool the sample, so that it was found that the resultant sample became white and turbid, thus being in a polycrystalline state.

### Comparative Example 2

As starting materials for synthesizing glass, Lu₂O₃ (purity: 99.99 wt. %) and Al₂O₃ (purity: 99.998 wt. %) were used. These starting materials were weighed and sufficiently mixed in a mortar in a weight ratio (Lu₂O₃:Al₂O₃) of 2.10:1 so that Lu₂O₃ and Al₂O₃ contain Lu in an amount of 35% in cation percent and Al in an amount of 65% in cation percent, respectively. Thereafter, about 100 mg of the mixture was partly melted by irradiation with a carbon dioxide gas laser and an output of the laser was lowered, so that a spherical polycrystalline aggregate was prepared.

This polycrystalline aggregate as a sample 1 was set on a copper nozzle 2 of the gas jet levitation device shown in FIG. 2 and was then heated again by the carbon dioxide gas laser 4 in a floating state created by using Ar gas 3, thus being completely melted. In that state, the output of the laser was cut off to abruptly cool the sample, so that it was found that the resultant sample became white and turbid, thus being in a polycrystalline state.

Results of Examples 1 to 4 and Comparative Examples 1 and 2 described above are shown in Table 1.

TABLE 1

| Ex. No. | Lu (%)*¹ | Al (%) *² | Vitrification |
|---|---|---|---|
| Comp. Ex. 1 | 22 | 78 | Not vitrified |
| Ex. 3 | 24 | 76 | Vitrified |
| Ex. 1 | 27 | 73 | Vitrified |
| Ex. 4 | 30 | 70 | Vitrified |
| Ex. 2 | 33 | 67 | Vitrified |
| Comp. Ex. 2 | 35 | 65 | Not Vitrified |

*¹Cation percent of Lu for Lu₂O₃
*²Cation percent of Al for Al₂O₃

### INDUSTRIAL APPLICABILITY

The glass composition for ultraviolet light according to the present invention is capable of suppressing an adverse influence due to intrinsic birefringence (IBR), so that the glass composition can be utilized as not only a lens for visible light but also a lens for ultraviolet light.

While the invention has been described with reference to the structures disclosed herein, it is not confined to the details set forth and this application is intended to cover such modifications or changes as may come within the purpose of the improvements or the scope of the following claims.

1-3. (canceled)

4. A sputtering target comprising:
a glass composition comprising Lu, Al, and O in an amount of 99.99 weight % or more in total,
wherein said glass composition comprises Lu in an amount of 24% or more and 33% or less in cation percent and Al in an amount of 67% or more and 76% or less in cation percent.

5. A sputtering target according to claim 4, wherein said glass composition further comprises boron.

6. A sputtering target according to claim 4, wherein said glass composition has impurities, other than Lu, Al, and O, present in an amount of 100 ppm or less.

7. A sputtering target according to claim 4, wherein said glass composition comprises Lu in an amount of 27% or more and 30% or less in cation percent and Al in an amount of 70% or more and 73% or less in cation percent.

8. A method comprising using a sputtering target according to claim 4 to form an optical thin film.

9. A method comprising:
providing an optical member comprising a base material; and
forming an optical thin film on the base material of the optical member, by sputtering,
wherein the optical thin film comprises a glass composition comprising Lu, Al, and O in an amount of 99.99 weight % or more in total, and
wherein the glass composition comprises Lu in an amount of 24% or more and 33% or less in cation percent and Al in an amount of 67% or more and 76% or less in cation percent.

10. A method according to claim 9, further comprising:
providing a light source for generating ultraviolet light; and
providing an optical system for irradiating an object with the ultraviolet light from the light source,
wherein the optical system comprises the optical member having the optical thin film formed on the base material thereof.

11. A method according to claim 9, wherein said forming an optical thin film by sputtering comprises:
sputtering using a sputtering target, the sputtering target comprising a glass composition comprising Lu, Al, and O in an amount of 99.99 weight % or more in total, wherein the glass composition comprises Lu in an amount of 24% or more and 33% or less in cation percent and Al in an amount of 67% or more and 76% or less in cation percent.

12. A method according to claim 11, wherein the glass composition of the sputtering target comprises Lu in an amount of 27% or more and 30% or less in cation percent and Al in an amount of 70% or more and 73% or less in cation percent.
